(19) United States
(12) Patent Application Publication
(10) Pub. No.: US 2025/0081598 A1
(43) Pub. Date: Mar. 6, 2025

(54) INTEGRATED CIRCUIT AND MANUFACTURING METHOD THEREOF

(71) Applicant: Taiwan Semiconductor Manufacturing Company, Ltd., Hsinchu (TW)

(72) Inventors: Ming-Heng Tsai, Taipei City (TW); Chun-Sheng Liang, Changhua County (TW); Ta-Chun LIN, Hsinchu (TW); Jhon Jhy Liaw, Hsinchu County (TW)

(73) Assignee: Taiwan Semiconductor Manufacturing Company, Ltd., Hsinchu (TW)

(21) Appl. No.: 18/460,578

(22) Filed: Sep. 3, 2023

(51) Int. Cl. H01L 27/088; H01L 21/768; H01L 21/8234; H01L 23/522

(52) U.S. Cl. CPC H10D 84/83; H01L 21/76804; H01L 23/5226; H10D 84/0149; H10D 84/038

(57) ABSTRACT

An integrated circuit and a formation method thereof are provided. The integrated circuit includes: an active structure, formed on a semiconductor substrate, and extending along a first lateral direction; first and second gate lines, extending along a second lateral direction on the semiconductor substrate, and crossing the active structure; an isolation wall, extending along the second lateral direction between the first and second gate lines, and cutting through the active structure; a first source/drain contact, extending along the second lateral direction between the first gate line and the isolation wall, and crossing the active structure; and a first source/drain via, disposed on the first source/drain contact, and laterally extending along the first direction to overlap the isolation wall.

### BACKGROUND

Along with quick development of semiconductor industry, integrated circuits have become more complicated in functionality and faster in operation speed, yet more compact in size. This miniaturization of integrated circuits includes scaling of active devices used in the integrated circuits (e.g., field effect transistors (FETs)), and further includes significantly reducing dimensions of interconnection elements for interconnecting the active devices. However, the dimension reduction of the interconnection elements would dramatically increase resistance along conduction paths between the active devices and conduction paths from the active devices to inputs/outputs (I/Os) of the integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic plan view illustrating a portion of an integrated circuit, according to some embodiments of the present disclosure.

FIG. 1B is a schematic cross-sectional view along X1-X1′ line shown in FIG. 1A, according to some embodiments of the present disclosure.

FIG. 2 is a flow diagram illustrating a method for forming the integrated circuit, according to some embodiments.

FIG. 3A through FIG. 3H are schematic cross-sectional views of the intermediate structures at various stages during the process flow shown in FIG. 2, and are taken along the X1-X1′ line shown in the resulted integrated circuit shown in FIG. 1A.

FIG. 4 is a schematic cross-sectional view taken along one of the elongated source/drain vias in an integrated circuit, according to some embodiments of the present disclosure.

FIG. 5A and FIG. 5B are respectively a schematic cross-sectional view taken along one of the elongated source/drain vias in an integrated circuit, according to some embodiments of the present disclosure.

FIG. 6A through FIG. 6D are respectively a schematic cross-sectional view taken along one of the elongated source/drain vias in an integrated circuit, according to some embodiments of the present disclosure.

FIG. 7A is a schematic plan view illustrating a portion of an integrated circuit, according to some embodiments of the present disclosure.

FIG. 7B is a schematic cross-sectional view along X2-X2′ line shown in FIG. 7A, according to some embodiments of the present disclosure.

FIG. 8 is a schematic plan view illustrating a portion of an integrated circuit, according to some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

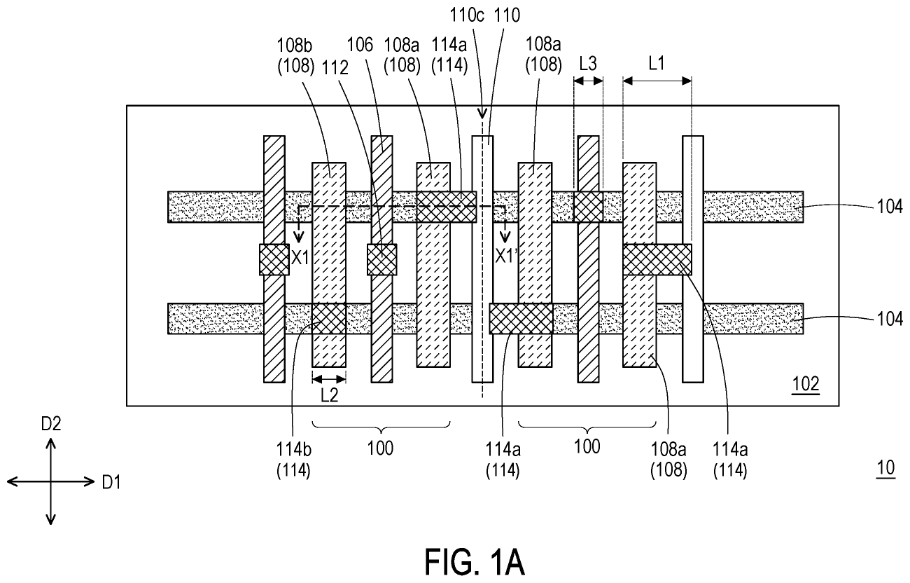

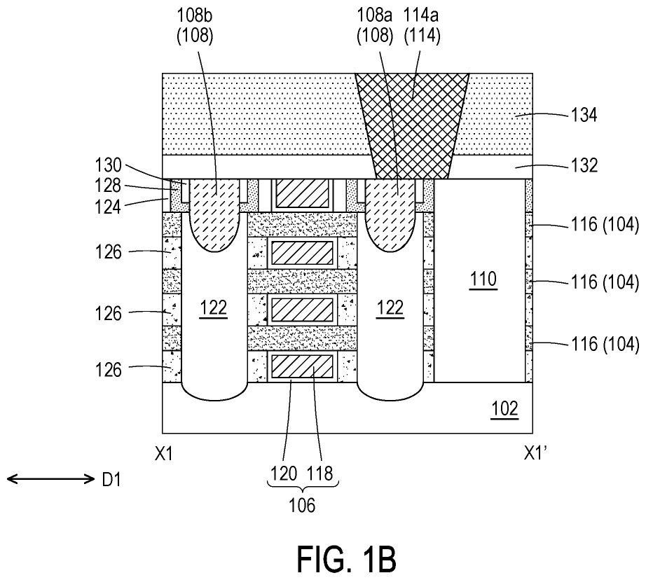

FIG. 1A is a schematic plan view illustrating a portion of an integrated circuit 10, according to some embodiments of the present disclosure.

Referring to FIG. 1A, the integrated circuit 10 includes field effect transistors (FETs) 100 formed on a semiconductor substrate 102 and respectively defined in a region where one or more active structures 104 is/are intersected with a gate line 106 and a pair of source/drain contacts 108 at opposite sides of the gate line 106. As an example illustrated in FIG. 1A, each FET 100 is defined in a region where two of the active structures 104 are intersected with one of the gate lines 106 and two of the source/drain contacts 108 at opposite sides of the one of the gate lines 106. In some embodiments, the active structures 104 extend along a lateral direction D1, whereas the gate lines 106 and the source/drain contacts 108 extend along a lateral direction D2 intersected with (e.g., perpendicular to) the lateral direction D1.

In a cell row of the integrated circuit 10, multiple ones of the FETs 100 may be defined along the same group of the active structures 104 (e.g., along two of the active structures 104 as shown in FIG. 1A). In order to provide proper isolation between adjacent ones of the FETs 100 arranged along the same group of the active devices 104, isolation walls 110 cut through the shared active structure(s) 104 are disposed between the adjacent FETs 100. As an interface between the adjacent FETs 100 is defined between two of the source/drain contacts 108 from the adjacent FETs 100 (also referred to as source/drain contacts 108a), the isolation wall 110 extending along such interface is located between the two source/drain contacts 108a. In the embodiments where the active structures 104 extend along the lateral direction D1 and the gate lines 106 as well as the source/drain contacts 108 extend along the lateral direction D2, the isolation walls 100 may extend along the lateral direction D2.

Although not shown, a stack of metallization layers are formed over the FETs 100, and interconnection elements (e.g., wires, vias, pads etc.) in the metallization layers are arranged to establish conduction paths between the FETs 100 and/or conduction paths from the FETs 100 to inputs/outputs (I/Os) of the integrated circuit 10. Gate vias 112 are disposed on the gate lines 106, to connect the gate lines 106 to the overlying interconnection elements. In a similar way, source/drain vias 114 are disposed on the source/drain contacts 108, to connect the source/drain contacts 108 to the overlying interconnection elements.

On the other hand, as being designed to provide electrical isolation rather than electrical connection, the isolation walls 110 are not required to be connected to the overlying interconnection elements. Nevertheless, the source/drain vias 114 disposed on the source/drain contacts 108a extending along opposite sides of the isolation walls 110 (also referred to as source/drain vias 114a) further extend to overlap the isolation walls 110. That is, each source/drain via 114a disposed on one of the source/drain contacts 108a laterally extends from such source/drain contact 108a, to reach and overlap the most adjacent isolation wall 110. In those embodiments where the active structures 104 extend along the lateral direction D1 and the gate lines 106, the source/drain contacts 108 and the isolation walls 110 extend along the lateral direction D2, the source/drain vias 114a may extend along the lateral direction D1. As further extended, the source/drain vias 114a are each formed with a greater footprint area, thus have a lower resistivity. In addition, the source/drain vias 114a can be in contact with the overlying interconnection elements by a greater contact area, and contact resistance between the source/drain vias 114a and the overlying interconnection elements can be effectively lowered. As a result, the electrical resistance along the conduction paths between the FETs 100 and/or the conduction paths from the FETs 100 to the I/Os can be lowered. Moreover, since the isolation walls 110 do not need to be routed to overlying interconnection elements through any via, regions above the isolation walls 110 should be open. Accordingly, the elongated source/drain vias 114a extending to these regions would not approximate other vias. Therefore, the elongated design of the source/drain vias 114a would result in described benefits without penalties, such as increase of resistance-capacitance delay (RC delay).

In some embodiments, multiple ones of the source/drain vias 114a may laterally extend to overlap the same isolation pillar 110. In order to reduce RC delay mutually resulted on the source/drain vias 114a overlapping the same isolation pillar 110, these source/drain vias 114a may be widely separated from one another. As an example shown in FIG. 1A, two of the source/drain vias 114a laterally extend to overlap the same isolation pillar 110 from opposite sides of such isolation pillar 110, and are widely separated along the lateral direction D2. More specifically, one of these source/drain vias 114a may overlap one of the active structures 104, whereas the other one of these source/drain vias 114a may overlap another one of the active structures 104.

On the other hand, other source/drain vias 114 (also referred to as source/drain vias 114b) and the gate vias 112 may be each formed within a more confined area. Specifically, while the source/drain vias 114a are respectively formed with a length L1 (along the lateral direction D1), the source/drain vias 114b may be each formed with a length L2 (along the lateral direction D1) less than the length L1, and the gate vias 112 may be each formed with a length L3 (along the lateral direction D1) 11 less than the length L1 as well. The length L1 is greater than a summation of a line width of each source/drain contact 108 and a shortest spacing between each source/drain contact 108a and the nearest isolation wall 110, whereas the length L2 approximates the line width of each source/drain contact 108, and the length L3 approximates a line width of each gate line 106. In some embodiments, each source/drain via 114a at most reaches a central line 110c of the overlapped isolation wall 110. In these embodiments, the length L1 is no greater than a summation of the line width of each source/drain contact 108, the shortest spacing between each source/drain contact 108a and the nearest isolation wall 110 and a half line width of each isolation wall 110.

According to the illustrated example, some of the source/drain vias 114 and the gate vias 112 overlap the active structures 104, whereas others of the source/drain vias 114 and the gate vias 112 are located between the active structures 104. However, it should be appreciated that, those skilled in the art can modify an arrangement of the source/drain vias 114 and the gate vias 112 according to circuit design, the present disclosure is not limited thereto.

FIG. 1B is a schematic cross-sectional view along X1-X1′ line shown in FIG. 1A, according to some embodiments of the present disclosure.

Referring to FIG. 1B, each active structure 104 includes a stack of channel structures 116 vertically spaced apart from one another and formed of a semiconductor material. The channel structures 116 may be respectively formed as a one-dimensional structure or a two-dimensional structure. For instance, the channel structures 116 may be nanosheets, nanorods, nanowires or the like.

The gate lines 106 wrap all around the intersecting channel structures 116, and may respectively include a gate electrode 118 and a gate dielectric layer 120 separating the gate electrode 118 from the intersecting channel structures 116. Although not shown, each gate line 106 may further include an interfacial layer separating the gate dielectric layer 120 from the intersecting channel structures 116. Further, the gate electrode 118 may by a multilayer structure, which includes at least one work function layer and an electrode layer (both not shown) covering the work function layer(s).

The channel structures 116 may have breaks at opposite sides of the intersecting gate lines 106, and epitaxial structures 122 may be filled in these breaks. In this way, the epitaxial structures 122 as source/drain terminals of the FETs 100 are in lateral contact with sections of the channel structures 116 wrapped by the gate lines 106. The source/drain contacts 108 may extend above the epitaxial structures 122, and are in contact with the epitaxial structures 122 from above. In some embodiments, the source/drain contacts 108 further protrude into the epitaxial structures 122. In these embodiments, the epitaxial structures 122 may have recessed top surfaces.

In some embodiments, the gate lines 106 are laterally separated from the epitaxial structures 122 via sidewall spacers 124 and inner spacers 126. The sidewall spacers 124 extend along sidewalls of the gate lines 106. In addition, the sidewall spacers 124 may have openings through which the channel structures 116 extend to reach the epitaxial structures 122, and the inner spacers 126 are filled in between the channel structures 116 in the openings.

In some embodiments, etching stop layers 128 and dielectric structures 130 are filled in recesses respectively defined over one of the epitaxial structures 122 and between adjacent ones of the sidewall spacers 124 along opposite sides of the one of the epitaxial structures 122. The etching stop layers 128 conformally cover surfaces of these recesses, and the dielectric structures 130 are formed on the etching stop layers 128 to fill up the recesses. In these embodiments, the source/drain contacts 108 extend through the dielectric structures 130 and the etching stop layers 128 to reach the epitaxial structures 122. Further, topmost surfaces of the etching stop layers 128 and the dielectric structures 130 may be substantially coplanar with topmost surfaces of the gate electrodes 118 and the gate dielectric layers 120.

During manufacturing, some of the originally formed gate lines 106 and portions of the channel structures 116 wrapped by these gate lines 106 are replaced by the isolation walls 110. That is, the isolation walls 110 are placed in spaces previously occupied by these gate lines 106 and the portions of the channel structures 116 wrapped by these gate lines 106, and are in lateral contact with the intersecting channel structures 116. Such replacement may be performed after formation of the sidewall spacers 124 and the inner spacers 126, and the isolation walls 110 may be laterally separated from the epitaxial structures 122 via the sidewall spacers 124 and the inner spacers 126 previously covering sidewalls of the gate lines 106 being replaced. Further, in some embodiments, top portions of the sidewall spacers 124 previously covering top portions of the gate lines 106 being replaced are removed during the replacement, and top portions of the resulted isolation walls 110 may be in lateral contact with the etching stop layers 128 aside the isolation walls 110. Moreover, in some embodiments, top surfaces of the isolation walls 110 are substantially coplanar with top surfaces of the gate lines 106 (including the gate electrodes 118 and the gate dielectric layers 120), the remained sidewall spacers 124, the etching stop layers 128, the dielectric structures 130 and the source/drain contacts 108.

As described with reference to FIG. 1A, the source/drain vias 114a are disposed on the source/drain contacts 108a adjacent to the isolation walls 110, and further extend to overlap the isolation walls 110. In those embodiments where the top surfaces of the source/drain contacts 108 are substantially leveled with the top surfaces of the isolation walls 110, the source/drain vias 114a may be in direct contact with the top surfaces of the source/drain contacts 108a and the isolation walls 110. In addition to be in contact with the source/drain contacts 108a and the isolation walls 110, the source/drain vias 114a may further in contact with the dielectric structures 130 and the etching stop layers 128 surrounding the source/drain contacts 108a. Moreover, in some embodiments, another etching stop layer 132 and a dielectric layer 134 are stacked on the top surfaces of the isolation walls 110, the gate lines 106 (including the gate electrodes 118 and the gate dielectric layers 120), the sidewall spacers 124, the etching stop layers 128, the dielectric structures 130 and the source/drain contacts 108. In these embodiments, the source/drain vias 114a extend through the dielectric layer 134 and the etching stop layer 132.

Although not shown in FIG. 1B, the gate vias 112 and others of the source/drain vias 114 (i.e., the source/drain vias 114b) may extend through the dielectric layer 134 and the etching stop layer 132 as well, to reach the gate electrodes 118 of the gate lines 106 and others of the source/drain contacts 108 (i.e., the source/drain contacts 108b), respectively.

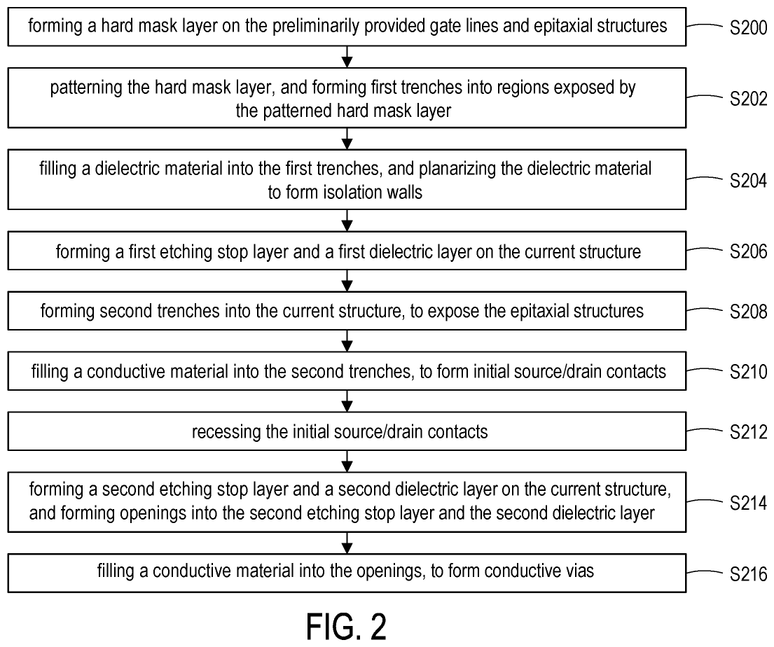

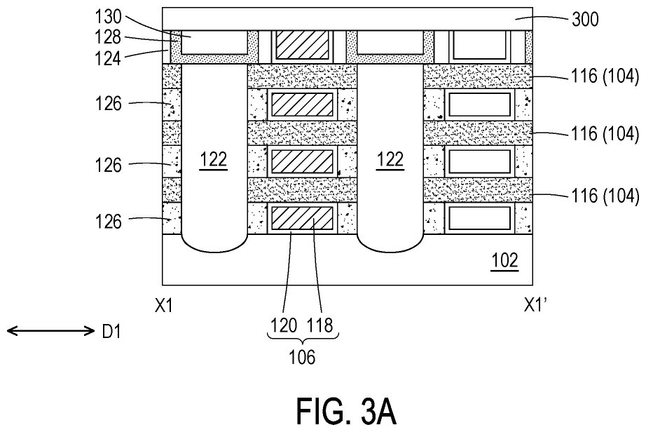

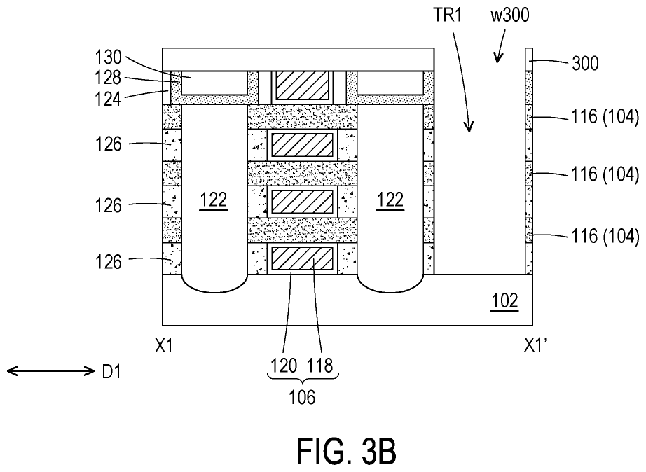

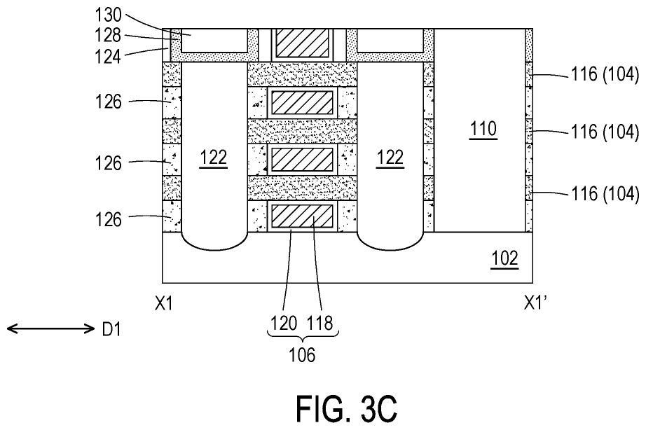

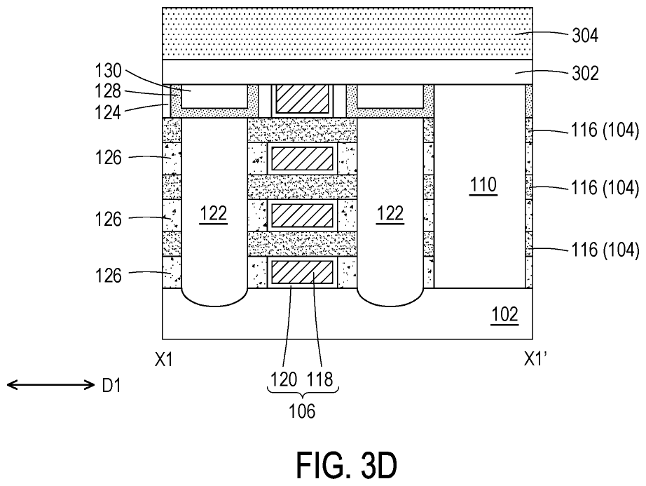

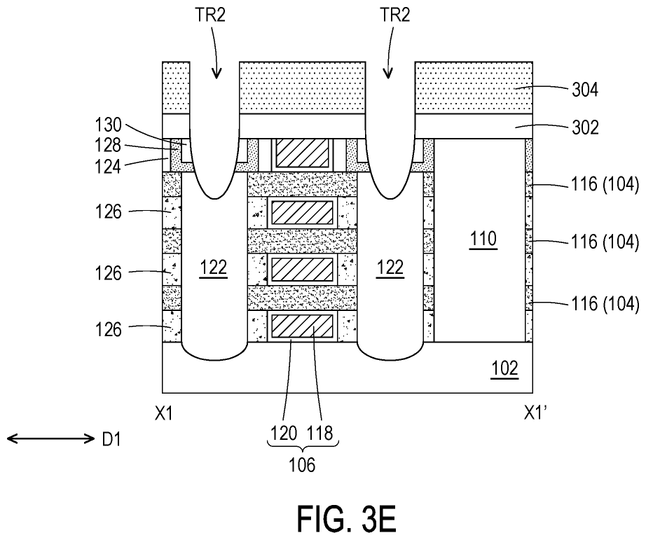

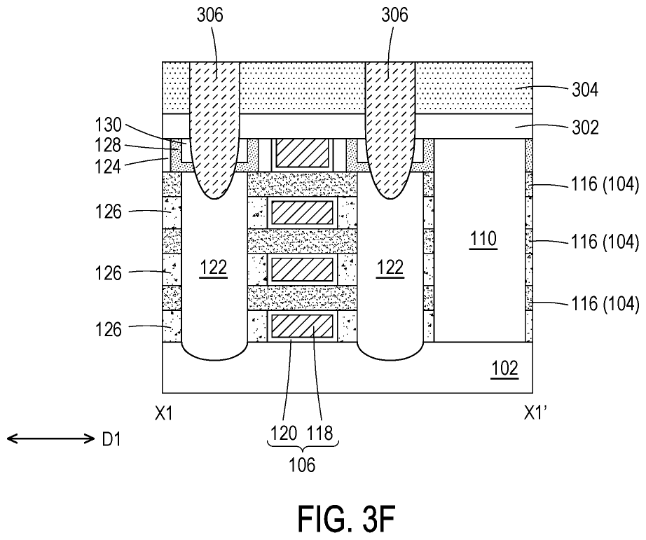

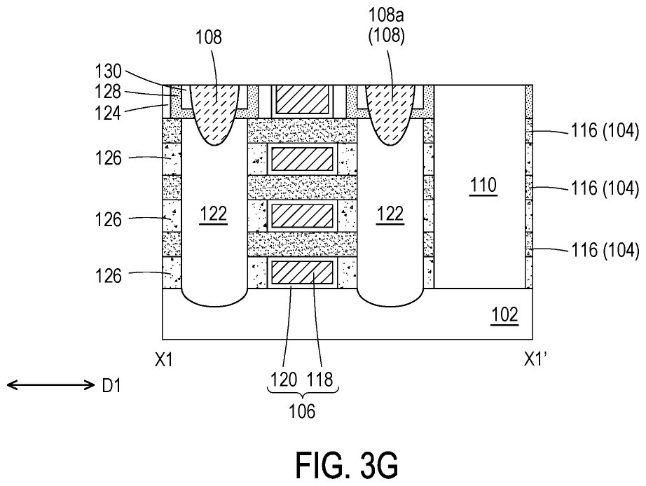

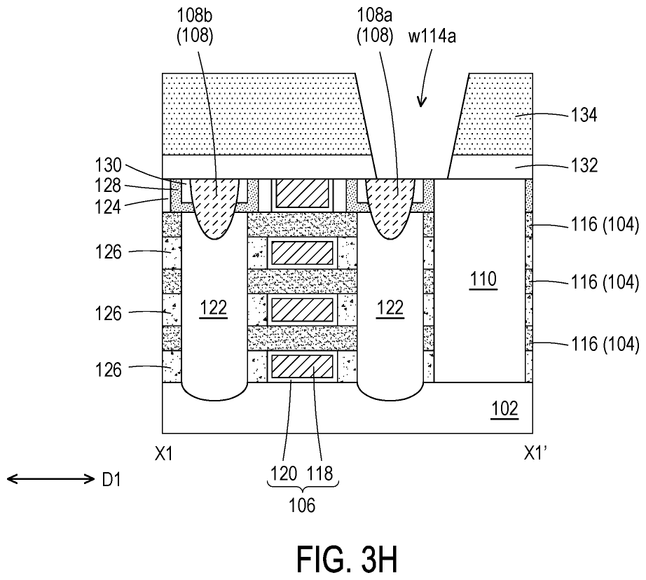

FIG. 2 is a flow diagram illustrating a method for forming the integrated circuit 10, according to some embodiments. FIG. 3A through FIG. 3H are schematic cross-sectional views of the intermediate structures at various stages during the process flow shown in FIG. 2, and are taken along the X1-X1′ line shown in the resulted integrated circuit 10 shown in FIG. 1A.

Prior to the process, the FETs 100 have been built on the semiconductor substrate 102 via any suitable method. Currently, none of the originally formed gate lines 106 and the channel structures 116 are replaced by any of the isolation walls 110, and the source/drain contacts 108, the etching stop layer 132, the dielectric layer 134, the gate vias 112 and the source/drain vias 114 have not been formed yet.

Referring to FIG. 2 and FIG. 3A, at a step S200, a hard mask layer 300 is formed over the preliminarily provided gate lines 106 and the epitaxial structures 122. In addition, the hard mask layer 300 may further cover the sidewall spacers 124, the etching stop layers 128 and the dielectric structures 130.

Referring to FIG. 2 and FIG. 3B, at a step S202, the hard mask layer 300 is patterned and the trenches TR1 are formed into regions exposed by the patterned hard mask layer 300. Specifically, openings w300 are formed in the hard mask layer 300 during the patterning, and the openings w300 expose the gate lines 106 to be replaced by the isolation walls 110. Subsequently, the exposed gate lines 106 and portions of the channel structures 116 wrapped by these gate lines 106 are removed to form the trenches TR1. In some embodiments, portions of the sidewall spacers 124 along top portions of the gate lines 106 being replaced are also exposed and then removed, and the etching stop layers 128 along opposite sides of the trenches TR1 are exposed at sidewalls of the trenches TR1. Further, in these embodiments, the inner spacers 126 along at opposite sides of the TR1 may be trimmed (laterally recessed).

Referring to FIG. 2 and FIG. 3C, at a step S204, a dielectric material is filled into the trenches TR1 and the openings w300, and planarized to form the isolation walls 110. Specifically, the planarization may be performed until the hard mask layer 300 is removed and the underlying gate lines 106, the sidewall spacers 124, the etching stop layers 128 and the dielectric structures 130 are exposed. As a result, the top surfaces of the isolation pillars 110 may be substantially coplanar with the top surfaces of the gate lines 106, the sidewall spacers 124, the etching stop layers 128 and the dielectric structures 130.

Referring to FIG. 2 and FIG. 3D, at a step S206, an etching stop layer 302 and a dielectric layer 304 are stacked on the current structure. As a result, the isolation walls 110, the gate lines 106, the sidewall spacers 124, the etching stop layers 128 and the dielectric structures 130 are covered.

Referring to FIG. 2 and FIG. 3E, at a step S208, trenches TR2 are formed into the current structure, to expose the epitaxial structures 122. Specifically, the trenches TR2 may penetrate through the dielectric layer 304, the etching stop layer 302, the dielectric structures 130 and the etching stop layers 128, to expose the epitaxial structures 122. In some embodiments, the trenches TR2 may further extend into the epitaxial structures 122.

Referring to FIG. 2 and FIG. 3F, at a step S210, a conductive material may be filled into the trenches TR2, to form initial source/drain contacts 306. The initial source/drain contacts 306 may be formed to a height higher than the top surfaces of the gate lines 106, the side wall spacers 124, the etching stop layers 128, the dielectric structures 130 and the isolation walls 110. In some embodiments, top surfaces of the initial source/drain contacts 306 are substantially coplanar with a top surface of the dielectric layer 304.

Referring to FIG. 2 and FIG. 3G, at a step S212, the current structure is planarized, such that the initial source/drain contacts 306 are recessed to form the source/drain contacts 108. In those embodiments where the top surfaces of the source/drain contacts 108 are substantially leveled with the top surfaces of the gate lines 106, the sidewall spacers 124, the etching stop layers 128, the dielectric structures 130 and the isolation pillars 110, the planarization is performed until the top surfaces of the gate lines 106, the sidewall spacers 124, the etching stop layers 128, the dielectric structures 130 and the isolation pillars 110 are exposed, and the etching stop layer 302 as well as the dielectric layer 304 may be removed during the planarization.

Referring to FIG. 2 and FIG. 3H, at a step S214, the etching stop layer 132 and the dielectric layer 134 are formed and patterned on the current structure. Initially, the etching stop layer 132 and the dielectric layer 134 may entirely cover the structure shown in FIG. 3G. In the subsequent patterning process, openings are formed through the dielectric layer 134 and the etching stop layer 132. Those openings include openings w114a for accommodating the elongated source/drain vias 114a. Each of the opening w114a exposes one of the source/drain contacts 108a and the nearest isolation wall 110, and also portions of the dielectric structure 130 and the etching stop layer 128 in between. In some embodiments, an etching process for forming the openings w114a may be performed until the underlying source/drain contacts 108a and the isolation walls 110 are exposed. In these embodiments, the openings w114a may not further extend to a depth below the top surfaces of the source/drain contacts 108a and the isolation walls 110. That is, in these embodiments, the openings w114a may not extend into the exposed portions of the dielectric structures 130 and the etching stop layers 128. Although not shown, in addition to the openings w114a for accommodating the extended source/drain vias 114a, those openings may further include openings for accommodating the gate vias 112 and openings for accommodating other source/drain vias 114 (i.e., the source/drain vias 114b).

Referring to FIG. 2 and FIG. 1B, at a step S216, a conductive material is filled into these openings, to form conductive vias including the elongated source/drain vias 114a.

Although not shown, more metallization layers are further formed over the current structure, to complete manufacturing of the integrated circuit 10. At the step S214 shown in FIG. 3H, the openings w114a are greater in size as compared to the underlying source/drain contacts 108a, thus sufficient exposure of the source/drain contacts 108a can be ensured, even when the openings w114a are slightly offset from designated positions. Accordingly, sufficient overlay between the source/drain vias 114a filled in the openings w114a and the underlying source/drain contacts 108a can be promised.

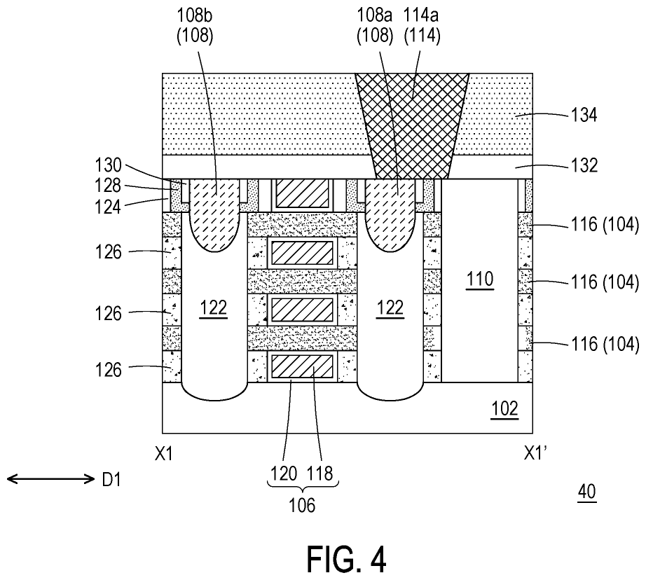

FIG. 4 is a schematic cross-sectional view taken along one of the elongated source/drain vias 114a in an integrated circuit 40, according to some embodiments of the present disclosure.

The integrated circuit 40 is identical with the integrated circuit 10 described with reference to FIG. 1A and FIG. 1B, except that a top portion of each isolation wall 110 in the integrated circuit 40 is in lateral contact with the adjacent etching stop layers 128 via remained sidewall spacers 124 in between. In this way, the source/drain vias 114a may further in contact with the remained sidewall spacers 124 in between the source/drain contacts 108a and the isolation walls 110.

The manufacturing process described with reference to FIG. 2 and FIG. 3A through FIG. 3H can be slightly modified, to be used for forming the integrated circuit 40. Specifically, at the step S202 described with reference to FIG. 3B, the openings w300 in the hard mask layer 300 may not entirely overlap top portions of the underlying sidewall spacers 124, thus the top portions of these sidewall spacers 124 may remain at top regions of the sidewalls of the trenches TR1 formed through the openings w300. Consequently, the top portion of each resulted isolation pillar 110 is in lateral contact with the remained sidewall spacers 124.

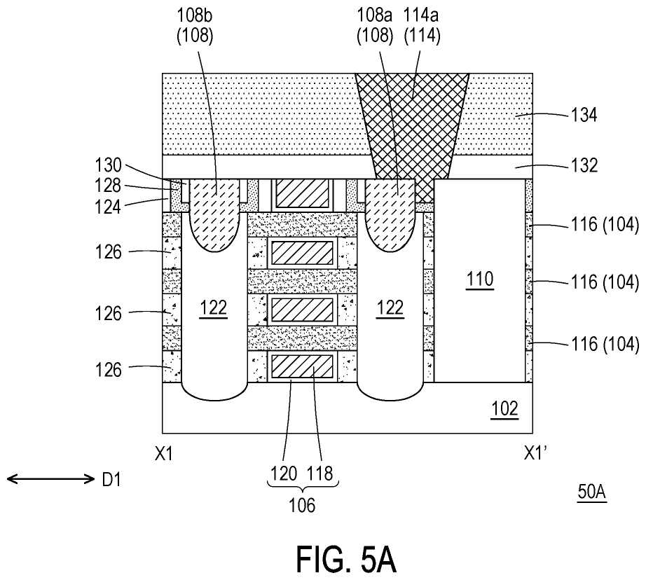

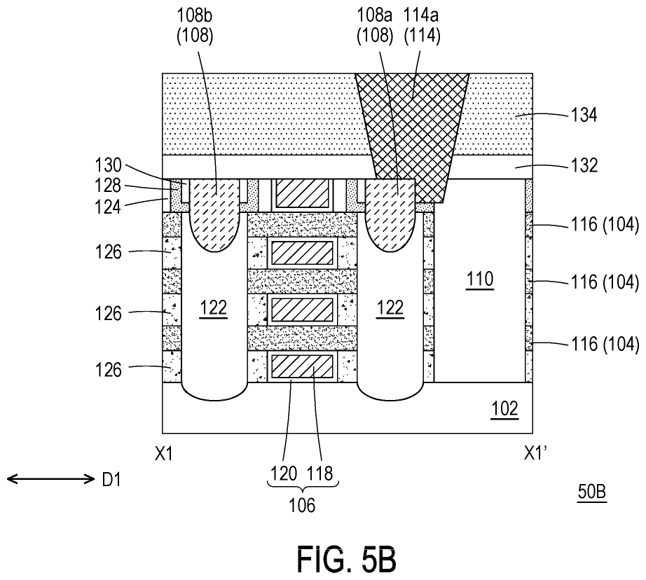

FIG. 5A is a schematic cross-sectional view taken along one of the elongated source/drain vias 114a in an integrated circuit 50A, according to some embodiments of the present disclosure.

The integrated circuit 50A is identical with the integrated circuit 10 described with reference to FIG. 1A and FIG. 1B, except that the source/drain vias 114a further extend to a height level lower than the top surfaces of the source/drain contacts 108 and the isolation walls 110. In these embodiments, the etching stop layers 128 and the dielectric structures 130 between the source/drain contacts 108a and the isolation walls 110 are recessed in corresponding to further extension of the source/drain vias 114a. In certain cases, portions of the dielectric structures 130 between the source/drain contacts 108a and the isolation walls 110 are completely removed, and portions of the etching stop layers 128 between the source/drain contacts 108a and the isolation walls 110 are partially removed. As further extending to be lower than the top surfaces of the source/drain contacts 108a and the isolation walls 110, the source/drain vias 114a are further in lateral contact with sidewalls of the source/drain contacts 108a. That is, each source/drain contact 108a is in contact with the overlapping source/drain via 114a by its top surface and sidewall. Owning to a greater contact area, contact resistance between each source/drain contact 108a and the overlapping source/drain via 114a can be further reduced. Moreover, the source/drain vias 114a may be in lateral and vertical contact with the isolation walls 110 as well.

The manufacturing process described with reference to FIG. 2 and FIG. 3A through FIG. 3H can be slightly modified, to be used for forming the integrated circuit 50A. Specifically, at the step S214 described with reference to FIG. 3H, the etching process for forming the openings w114a may be stopped after exposure of the top surfaces of the source/drain contacts 108a and the isolation pillars 110. In this way, the openings w114a may further extend into the dielectric structures 130 and the etching stop layers 128 between the source/drain contacts 108a and the isolation pillars 110. Accordingly, after filling a conductive material into such openings w114a, the source/drain vias 114a each shown in FIG. 5A can be resulted.

FIG. 5B is a schematic cross-sectional view taken along one of the elongated source/drain vias 114a in an integrated circuit 50B, according to some embodiments of the present disclosure.

The integrated circuit 50B is substantially identical with the integrated circuit 50A described with reference to FIG. 5A, except that the source/drain vias 114a in the integrated circuit 50B further extend into the isolation walls 110. As shown in FIG. 5B, a top edge of each isolation wall 110 is dented in corresponding to the further extension of the overlapping source/drain via 114a. The manufacturing process for forming the integrated circuit 50A as shown in FIG. 5A can be used for forming the integrated circuit 50B shown in FIG. 5B, except that etchant capable of reacting with the isolation wall 110 may be included in the etching process for forming the openings accommodating the source/drain vias 114a.

It should be noted that, the variation described with reference to FIG. 4 can also be used in the embodiments shown in FIG. 5A and FIG. 5B. In such alternative embodiments, the remained sidewall spacers 124 between the source/drain contacts 108a and top portions of the isolation walls 110 may be recessed in corresponding to the further extension of the source/drain vias 114a, and may be partially or completely removed.

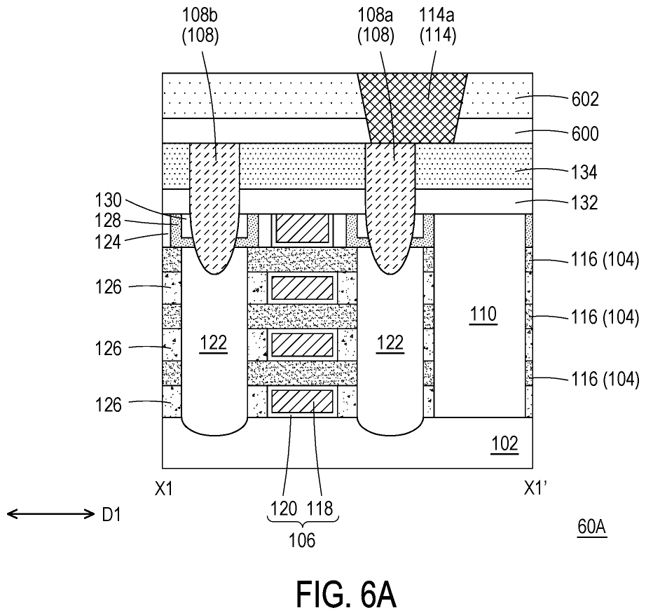

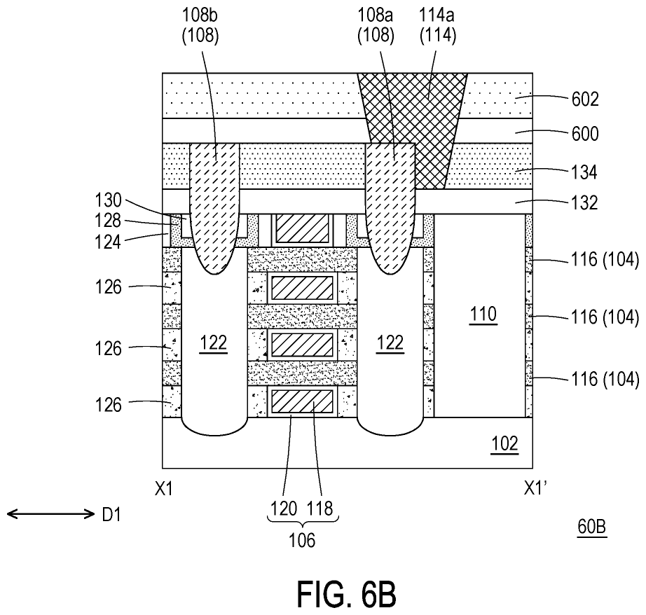

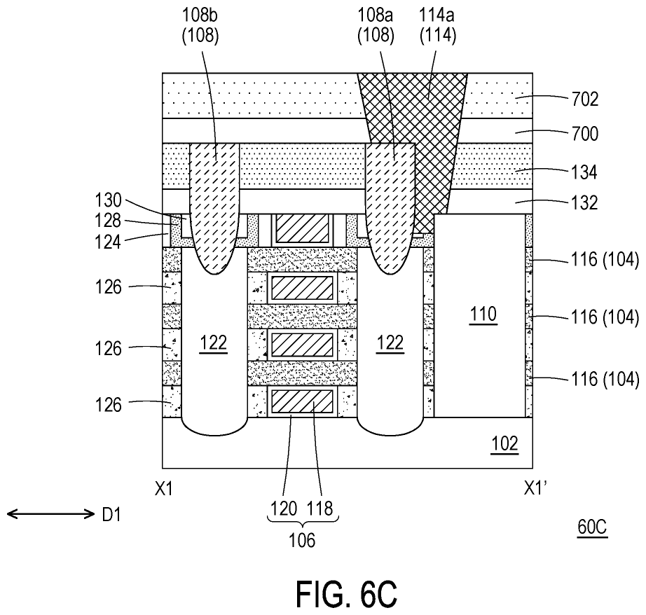

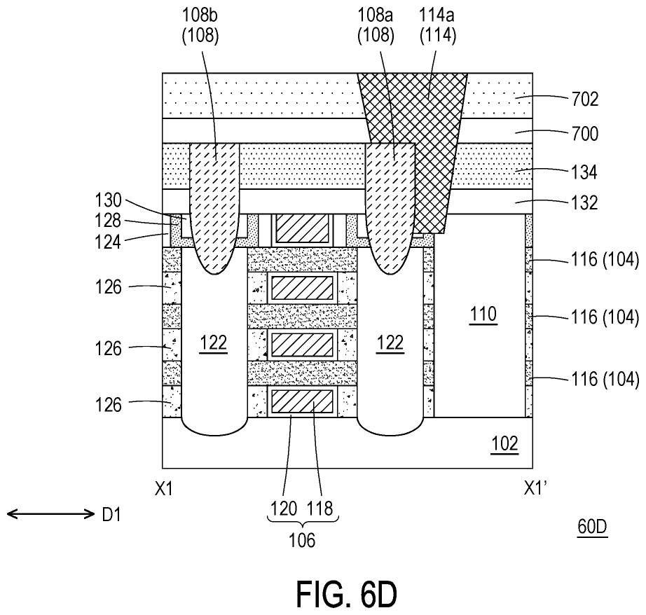

FIG. 6A is a schematic cross-sectional view taken along one of the elongated source/drain vias 114a in an integrated circuit 60A, according to some embodiments of the present disclosure.

The integrated circuit 60A is similar to the integrated circuit 10 described with reference to FIG. 1A and FIG. 1B, except that the source/drain contacts 108a extend to a height level higher than the top surfaces of the isolation walls 110 (and also higher than the top surfaces of the gate lines 106, the sidewall spacers 124, the etching stop layers 128 and the dielectric structures 130), and the source/drain vias 114a disposed on top of the source/drain contacts 108a are elevated from the isolation walls 110. In these embodiments, the source/drain contacts 108a may penetrate through the dielectric layer 134 and the etching stop layer 132. Further, another etching stop layer 600 and another dielectric layer 602 may be stacked on the dielectric layer 134, and the source/drain vias 114a may extend through the dielectric layer 602 and the etching stop layer 600, to establish contact with the source/drain contacts 108a.

The manufacturing process described with reference to FIG. 2 and FIG. 3A through FIG. 3H can be slightly modified, to be used for forming the integrated circuit 60A. Specifically, formation of the etching stop layer 302 and the dielectric layer 304 as shown in FIG. 3F may be omitted, and trenches for accommodating the source/drain contacts 108a may be formed after formation of the etching stop layer 132 and the dielectric layer 134. As these trenches are filled by a conductive material, the source/drain contacts 108a shown in FIG. 6A are formed. Thereafter, the additional etching stop layer 600 and dielectric layer 602 are stacked on the dielectric layer 134, and openings for accommodating the source/drain vias 114a are formed through the additional dielectric layer 702 and etching stop layer 700. As a conductive material is filled into these openings, the source/drain vias 114a as shown in FIG. 6A are formed.

FIG. 6B is a schematic cross-sectional view taken along one of the elongated source/drain vias 114a in an integrated circuit 60B, according to some embodiments of the present disclosure.

The integrated circuit 60B is substantially identical with the integrated circuit 60A described with reference to FIG. 6A, except that the source/drain vias 114a further extend to a height level lower than top surfaces of the source/drain contacts 108a and are in lateral contact with the source/drain contacts 108a. As shown in FIG. 6B, each source/drain vias 114a extends through the dielectric layer 134 to reach a top surface of the etching stop layer 132, and covers a sidewall of the overlapped source/drain contact 108a. That is, each source/drain contact 108a is in contact with the overlapping source/drain via 114a by its top surface and sidewall. Owning to a greater contact area, contact resistance between each source/drain contact 108a and the overlapping source/drain via 114a can be further reduced.

The manufacturing process for forming the integrated circuit 60A as shown in FIG. 6A can be used for forming the integrated circuit 60B, except that the etching process for forming the openings accommodating the source/drain vias 114a is stopped after exposure of the top surfaces of the source/drain contacts 108a. For instance, such etching process may be performed until exposure of the top surface of the etching stop layer 132. As a conductive material is filled in these openings, the source/drain vias 114a each shown in FIG. 60B can be resulted.

FIG. 6C is a schematic cross-sectional view taken along one of the elongated source/drain vias 114a in an integrated circuit 60C, according to some embodiments of the present disclosure.

The integrated circuit 60C is substantially identical with the integrated circuit 60B described with reference to FIG. 6B, except that the he source/drain vias 114a further extend to a height level lower than the top surfaces of the isolation walls 110 and are in vertical and lateral contact with the isolation walls 110. As shown in FIG. 6C, the source/drain vias 114a may penetrate through the etching stop layer 132, and further extend into the dielectric structures 130 and the etching stop layers 128 in between the source/drain contacts 108a and the isolation walls 110. Correspondingly, the dielectric structures 130 and the etching stop layers 128 in between the source/drain contacts 108a and the isolation walls 110 may be recessed, and may be partially or completely removed.

The manufacturing process for forming the integrated circuit 60B as shown in FIG. 6B can be used for forming the integrated circuit 60C, except that the etching process for forming the openings accommodating the source/drain vias 114a is stopped after exposure of the top surfaces of the isolation walls 110. As a conductive material is filled in these openings, the source/drain vias 114a each shown in FIG. 60C can be resulted.

FIG. 6D is a schematic cross-sectional view taken along one of the elongated source/drain vias 114a in an integrated circuit 60D, according to some embodiments of the present disclosure.

The integrated circuit 60D is substantially identical with the integrated circuit 60C described with reference to FIG. 6C, except that the source/drain vias 114a in the integrated circuit 60D further extend into the isolation walls 110. As shown in FIG. 6D, a top edge of each isolation wall 110 is dented in corresponding to the further extension of the overlapping source/drain via 114a. The manufacturing process for forming the integrated circuit 60C as shown in FIG. 6C can be used for forming the integrated circuit 60D shown in FIG. 6D, except that etchant capable of reacting with the isolation wall 110 may be included in the etching process for forming the openings accommodating the source/drain vias 114a. As a conductive material is filled in these openings, the source/drain vias 114a each shown in FIG. 60D can be resulted.

It should be noted that, the variation described with reference to FIG. 4 can also be used in the embodiments shown in FIG. 6A through FIG. 6D. In such alternative embodiments, the sidewall spacers 124 may remain on sidewalls of top portions of the isolation walls 110, and may be further recessed or removed.

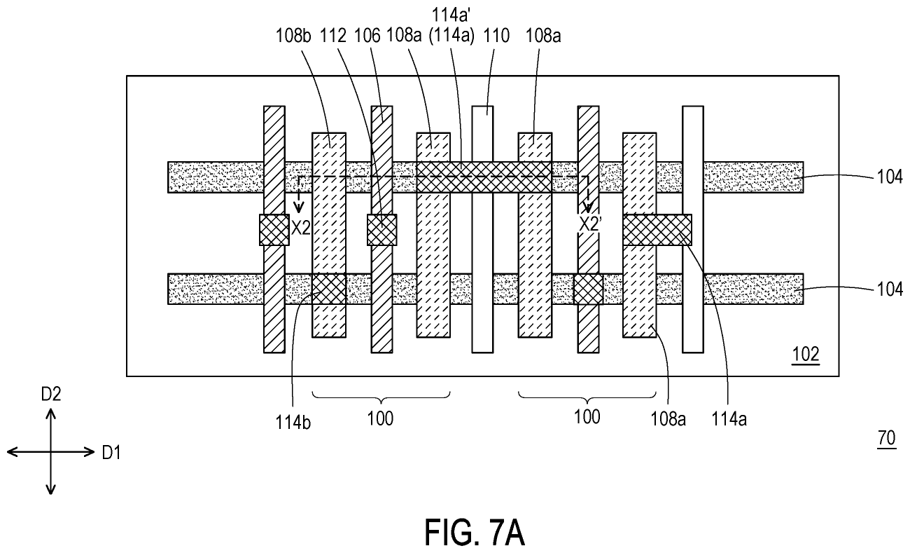

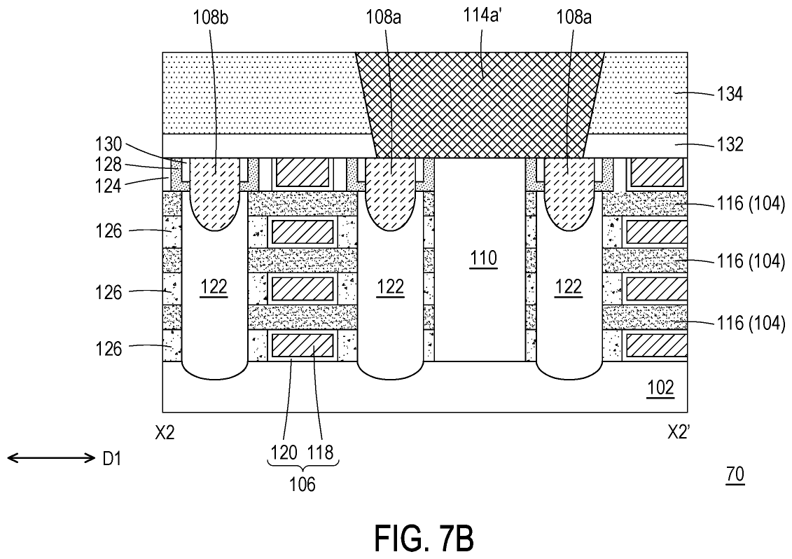

FIG. 7A is a schematic plan view illustrating a portion of an integrated circuit 70, according to some embodiments of the present disclosure. FIG. 7B is a schematic cross-sectional view along X2-X2′ line shown in FIG. 7A, according to some embodiments of the present disclosure.

The integrated circuit 70 is similar to the integrated circuit 10 as described with reference to FIG. 1A and FIG. 1B, except that at least one of the elongated source/drain vias 114a in the integrated circuit 70 (also referred to as source/drain via(s) 114a′) further extend across the overlapped isolation wall 110, to bridge the source/drain contacts 108a along opposite sides of this isolation wall 110. The bridged source/drain contacts 108a are electrically coupled together through the overlying source/drain via 114a′. As compared to others of the source/drain vias 114a only connected to one of the source/drain contacts 108a, the source/drain via(s) 114a′ has a longer length along the lateral direction D1.

As shown in FIG. 7B, according to some embodiments, the source/drain via 114a has a substantially flat bottom surface extending along and in contact with the top surfaces of the bridged source/drain contacts 108a and the top surfaces of the isolation wall 110, the dielectric structures 130 and the etching stop layer 128 in between the bridged source/drain contacts 108a.

Although not shown, the source/drain via 114a′ may further extend into the dielectric structures 130 and the etching stop layers 128 in between the bridged source/drain contacts 108a, such that bottom ends of the source/drain vias 114a′ may be lower than the top surfaces of the source/drain contacts 108a and the isolation walls 110, and the source/drain via 114a′ may be in lateral contact with the bridged source/drain contacts 108a and the overlapped isolation wall 110. In further embodiments, the source/drain via 114a′ further extends into the overlapped isolation wall 110, and the isolation wall 110 is recessed with respect to the bridged source/drain contacts 108a.

Moreover, in some embodiments, the source/drain contacts 108a may extend to a height level higher than the top surface of the isolation walls 110. In these embodiments, the source/drain via 114a′ may be elevated from the overlapped isolation wall 110. As an example similar to the source/drain via 114a shown in FIG. 6A, the source/drain via 114a′ may be in contact with the overlapped source/drain contacts 108a from above. As another example similar to the source/drain via 114a shown in FIG. 6B, the source/drain via 114a′ may be in vertical and lateral contact with the overlapped source/drain contacts 108a. Alternatively, as similar to the source/drain via 114a shown in FIG. 6C and FIG. 6D, the source/drain via 114a′ may further extend to a height level lower than the top surface of the overlapped isolation wall 110, and may be in contact with the isolation wall 110.

Furthermore, the variation described with reference to FIG. 4 can also be used in the embodiments described with reference to FIG. 7A and FIG. 7B. In such alternative embodiments, the sidewall spacers 124 may remain on sidewalls of top portions of the isolation walls 110, and may be further recessed or removed.

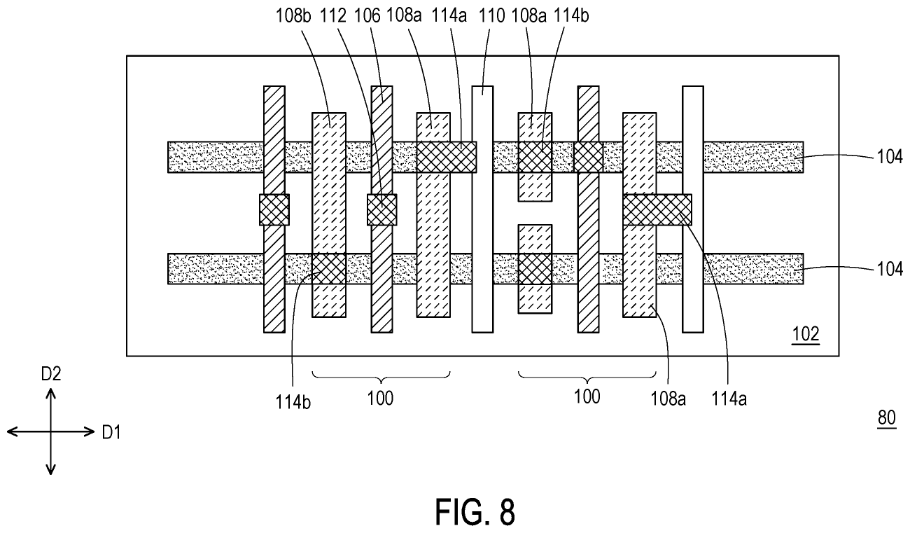

FIG. 8 is a schematic plan view illustrating a portion of an integrated circuit 80, according to some embodiments of the present disclosure.

According to the embodiments described with reference to FIG. 1A, each source/drain contact 108a is connected to one of the elongated source/drain via 114a extending to overlap the adjacent isolation wall 110, and continuously extends across multiple ones of the active structures 104. In addition, each of the isolation walls 110 (e.g., a central one shown in FIG. 1A) is overlapped with the elongated source/drain vias 114a extended from the source/drain contacts 108a at opposite sides of this isolation wall 110. On the other hand, in the embodiments shown in FIG. 8, not every source/drain contact 108a is connected to an elongated source/drain via 114a laterally extending to overlap the adjacent isolation wall 110. As an example shown in FIG. 8, the source/drain contacts 108a at a right side of a central one of the isolation walls 110 are not connected any of the elongated source/drain contacts 108a laterally extending to over the central isolation wall 110. Instead, these source/drain contacts 108a at the right side of the central isolation wall 110 are connected to the source/drain vias 114b not further extending to overlap the central isolation wall 110, and separately extend across the active structures 104.

That is, according to the embodiments shown in FIG. 8, while some of the source/drain contacts 108a (i.e., the source/drain contacts 108 each extending along an interface between adjacent FETs 100) are connected to the elongated source/drain vias 114a, others of the source/drain contacts 108a may not be connected to any of the elongated source/drain vias 114a.

As above, an integrated circuit is provided. The integrated circuit includes FETs arranged along cell rows. In each cell row, adjacent ones of the FETs are isolated from each other via an isolation wall. Each isolation wall is disposed in between a pair of source/drain contacts from adjacent ones of the FETs. As being designed to provide electrical isolation rather than electrical connection, the isolation walls are not required to be routed to overlying interconnection elements. Nevertheless, source/drain vias disposed on the source/drain contacts adjacent to the isolation walls, at least in part, further extend to overlap the isolation walls. As further extended, these source/drain vias are each formed with a greater footprint area, thus have a lower resistivity. In addition, sufficient contact area and low contact resistance between these elongated source/drain vias and the underlying source/drain contacts can be ensured, even if there is overlay issue between the elongated source/drain vias and the underlying source/drain contacts. Moreover, since the isolation walls are not required to be routed, regions over the isolation walls should be free of vias extending from the isolation walls. Accordingly, the elongated source/drain vias extending to these regions would not approximate other vias. Therefore, the elongated source/drain vias would result in the described benefits, without penalties such as increase of RC delay.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In an aspect of the present disclosure, an integrated circuit is provided. The integrated circuit comprises: an active structure, formed on a semiconductor substrate, and extending along a first lateral direction; first and second gate lines, extending along a second lateral direction on the semiconductor substrate, and crossing the active structure; an isolation wall, extending along the second lateral direction between the first and second gate lines, and cutting through the active structure; a first source/drain contact, extending along the second lateral direction between the first gate line and the isolation wall, and crossing the active structure; and a first source/drain via, disposed on the first source/drain contact, and laterally extending along the first direction to overlap the isolation wall.

In another aspect of the present disclosure, an integrated circuit is provided. The integrated circuit comprises: a stack of channel structures, extending along a first lateral direction on a semiconductor substrate; a gate line, crossing the channel structures along a second lateral direction on the semiconductor substrate, and wrapping around each of the channel structures; first and second epitaxial structures, disposed on the semiconductor substrate at opposite sides of the gate line, and extending through the channel structures along a vertical direction; first and second source/drain contacts, extending along the second lateral direction over the first and second epitaxial structures, and are in contact with the first and second epitaxial structures, respectively; an isolation wall, cutting through the channel structures along the second lateral direction, wherein the first epitaxial structure and the first source/drain contact are located between the gate line and the isolation wall; and a source/drain via, disposed on the first source/drain contact, and further extending along the first lateral direction to overlap the isolation wall.

In yet another aspect of the present disclosure, a method for forming an integrated circuit is provided. The method comprises: forming a stack of channel structures on a semiconductor substrate; forming first and second gate lines intersecting and wrapping around the channel structures; forming first and second epitaxial structures at opposite sides of the first gate line, wherein the first and second epitaxial structures vertically extend through the channel structures; replacing the second gate line and portions of the channel structures wrapped by the second gate line with an isolation wall; forming first and second source/drain contacts on the first and second epitaxial structures respectively, wherein the first epitaxial structure and the first source/drain contact are located between the first gate line and the isolation wall; and forming a source/drain via on the first source/drain contact, wherein the source/drain via further extends to overlap the isolation wall.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
an active structure, formed on a semiconductor substrate, and extending along a first lateral direction;
first and second gate lines, extending along a second lateral direction on the semiconductor substrate, and crossing the active structure;
an isolation wall, extending along the second lateral direction between the first and second gate lines, and cutting through the active structure;
a first source/drain contact, extending along the second lateral direction between the first gate line and the isolation wall, and crossing the active structure; and
a first source/drain via, disposed on the first source/drain contact, and laterally extending along the first direction to overlap the isolation wall.

2. The integrated circuit according to claim 1, further comprising:
a second source/drain contact, extending along the second lateral direction between the second gate line and the isolation wall, and crossing the active structure; and
a second source/drain via, disposed on the second source/drain contact, and laterally extending along the first direction to overlap the isolation wall.

3. The integrated circuit according to claim 2, wherein the first and second source/drain vias are spaced apart from each other along the second lateral direction.

4. The integrated circuit according to claim 2, wherein the first and second source/drain vias at most extend to a central line of the isolation wall from opposite sides of the isolation wall.

5. The integrated circuit according to claim 1, further comprising:
a second source/drain contact, extending along the second lateral direction between the second gate line and the isolation wall, and crossing the active structure, wherein the first source/drain via extends across the isolation wall from above and establish contact with both of the first and second source/drain contacts.

6. The integrated circuit according to claim 1, further comprising:
a second source/drain contact, extending along the second lateral direction between the second gate line and the isolation wall, and crossing the active structure; and
a second source/drain via, disposed on the second source/drain contact, wherein the second source/drain via is laterally spaced apart from the isolation wall.

7. An integrated circuit, comprising:
a stack of channel structures, extending along a first lateral direction on a semiconductor substrate;
a gate line, crossing the channel structures along a second lateral direction on the semiconductor substrate, and wrapping around each of the channel structures;
first and second epitaxial structures, disposed on the semiconductor substrate at opposite sides of the gate line, and extending through the channel structures along a vertical direction;
first and second source/drain contacts, extending along the second lateral direction over the first and second epitaxial structures, and are in contact with the first and second epitaxial structures, respectively;
an isolation wall, cutting through the channel structures along the second lateral direction, wherein the first epitaxial structure and the first source/drain contact are located between the gate line and the isolation wall; and
a source/drain via, disposed on the first source/drain contact, and further extending along the first lateral direction to overlap the isolation wall.

8. The integrated circuit according to claim 7, wherein a top surface of the first source/drain contact is substantially coplanar with a top surface of the isolation wall, and the source/drain via lands on the top surfaces of the first source/drain contact and the isolation wall.

9. The integrated circuit according to claim 8, wherein a bottom portion of the source/drain via further extends to a height level lower than the top surfaces of the first source/drain contact and the isolation wall, and is in lateral contact with the first source/drain contact and the isolation wall.

10. The integrated circuit according to claim 9, wherein a top edge is dented in corresponding to the bottom portion of the source/drain via.

11. The integrated circuit according to claim 7, wherein a top surface of the first source/drain contact is higher than a top surface of the isolation wall.

12. The integrated circuit according to claim 11, wherein a bottom surface of the source/drain via is in contact with the source/drain contact and elevated from the top surface of the isolation wall.

13. The integrated circuit according to claim 12, wherein the source/drain via is in vertical and lateral contact with the first source/drain contact.

14. The integrated circuit according to claim 11, wherein the source/drain via extends downwardly to a height level lower than the top surface of the isolation wall, and is in vertical and lateral contact with both of the first source/drain contact and the isolation wall.

15. A method for forming an integrated circuit, comprising:
forming a stack of channel structures on a semiconductor substrate;
forming first and second gate lines intersecting and wrapping around the channel structures;
forming first and second epitaxial structures at opposite sides of the first gate line, wherein the first and second epitaxial structures vertically extend through the channel structures;
replacing the second gate line and portions of the channel structures wrapped by the second gate line with an isolation wall;
forming first and second source/drain contacts on the first and second epitaxial structures respectively, wherein the first epitaxial structure and the first source/drain contact are located between the first gate line and the isolation wall; and
forming a source/drain via on the first source/drain contact, wherein the source/drain via further extends to overlap the isolation wall.

16. The method for forming the integrated circuit according to claim 15, wherein formation of the source/drain via comprises:
forming a stack of insulating layers on the first source/drain contact and the isolation wall;
performing an etching process to form an opening through the insulating layers; and
filling a conductive material in the opening, to form the source/drain via.

17. The method for forming the integrated circuit according to claim 16, wherein the etching process performed until exposure of top surfaces of the first source/drain contact and the isolation wall.

18. The method for forming the integrated circuit according to claim 16, wherein the etching process is stopped after exposure of top surfaces of the first source/drain contact and the isolation wall.

19. The method for forming the integrated circuit according to claim 18, wherein a top edge of the isolation wall is dented during the etching process.

20. The method for forming the integrated circuit according to claim 16, wherein the first source/drain contact is formed to a height level higher than a top surface of the isolation wall, and the etching process is performed until exposure of a top surface of the first source/drain contact, or stopped after exposure of the top surface of the first source/drain contact.
